(19) United States
(12) Patent Application Publication
(10) Pub. No.: US 2020/0102478 A1
(43) Pub. Date: Apr. 2, 2020

(54) CHEMICAL MECHANICAL POLISHING COMPOSITION AND METHOD OF POLISHING SILCON DIOXIDE OVER SILICON NITIRIDE

(71) Applicant: Rohm and Haas Electronic Materials CMP Holdings, Inc., Newark, DE (US)

(72) Inventors: Naresh Kumar Penta, Bear, DE (US); Robert L. Auger, Jhunan (TW)

(21) Appl. No.: 16/582,171

(22) Filed: Sep. 25, 2019

Related U.S. Application Data
(62) Division of application No. 16/145,339, filed on Sep. 28, 2018.

(51) Int. Cl. C09G 1/02; H01L 21/321

(52) U.S. Cl. CPC C09G 1/02; H01L 21/3212

(57) ABSTRACT

A chemical mechanical polishing composition for polishing silicon dioxide over silicon nitride includes certain acidic heterocyclic nitrogen compounds having a pK value of 5 of less. Also, methods for polishing a substrate to remove some of the silicon dioxide and silicon nitride are disclosed.

### FIELD OF THE INVENTION

The present invention is directed to a chemical mechanical polishing composition and method of polishing silicon dioxide over silicon nitride. More specifically, the present invention is directed to a chemical mechanical polishing composition and method of polishing silicon dioxide over silicon nitride, wherein the chemical mechanical polishing composition includes select acidic heterocyclic nitrogen compounds having pK values of 5 or less.

### BACKGROUND OF THE INVENTION

In the fabrication of integrated circuits and other electronic devices, multiple layers of conducting, semiconducting and dielectric materials are deposited on or removed from a surface of a semiconductor wafer. Thin layers of conducting, semiconducting, and dielectric materials can be deposited by a number of deposition techniques. Common deposition techniques in modern processing include physical vapor deposition (PVD), also known as sputtering, chemical vapor deposition (CVD), plasma-enhanced chemical vapor deposition (PECVD), and electrochemical plating (ECP).

As layers of materials are sequentially deposited and removed, the uppermost surface of the wafer becomes non-planar. Because subsequent semiconductor processing (e.g., metallization) requires the wafer to have a flat surface, the wafer needs to be planarized. Planarization is useful in removing undesired surface topography and surface defects, such as rough surfaces, agglomerated materials, crystal lattice damage, scratches, and contaminated layers or materials.

Chemical mechanical planarization, or chemical mechanical polishing (CMP), is a common technique used to planarize substrates, such as semiconductor wafers. In conventional CMP, a wafer is mounted on a carrier assembly and positioned in contact with a polishing pad in a CMP apparatus. The carrier assembly provides a controllable pressure to the wafer, pressing it against the polishing pad. The pad is moved (e.g., rotated) relative to the wafer by an external driving force. Simultaneously therewith, a polishing composition (“slurry”) or other polishing solution is provided between the wafer and the polishing pad. Thus, the wafer surface is polished and made planar by the chemical and mechanical action of the pad surface and slurry.

Certain advanced device designs demand polishing compositions that provide enhanced silicon oxide removal efficiency at lower point-of-use (POU) abrasive wt %. For example, in front-end-of-line (FEOL) semiconductor processing, shallow trench isolation (STI) is critical to the formation of gates in integrated circuit fabrication, such as prior to formation of the transistors. In shallow trench isolation (STI), a dielectric such as tetraethyl orthosilicate (TEOS) or silicon dioxide is deposited in excess in openings formed in the silicon wafer, for example, a trench or isolation area which is isolated from the remainder of the integrated circuit by silicon nitride (Si₃N₄) barrier. A CMP process is then used to remove the excess dielectric resulting in a structure in which a predetermined pattern of the dielectric is inlaid in the silicon wafer. CMP for STI requires the removal and planarization of the silicon dioxide overburden from the isolation areas, thereby resulting in a coplanar surface with the silicon dioxide-filled trenches. In STI, the silicon nitride film surfaces must be cleared of the silicon dioxide to allow subsequent removal of the silicon nitride hard mask in downstream processing. An acceptable silicon dioxide:silicon nitride removal rate ratio is necessary to prevent damage to the underlying silicon active areas and provide an overpolish margin to ensure all pattern densities are cleared of the silicon dioxide.

Presently, users of aqueous chemical mechanical planarization polishing compositions used with CMP polishing pads to polish substrates desire to avoid the use of ceria containing CMP polishing compositions. Ceria slurries show high selectivity for silicon dioxide over silicon nitride and avoid removal of silicon dioxide in the trench area upon exposure of silicon nitride, but are costly, have issues with removal rate (RR) and process stability, and are prone to causing defects during polishing. Silica slurry formulations offer lower cost, defect-free solutions, but, to date, have suffered from unsatisfactory inadequate silicon dioxide:silicon nitride selectivity for use in STI applications

Accordingly, there is a need for polishing compositions and polishing methods that exhibit desirable planarization efficiency, uniformity, and selective removal of silicon dioxide over silicon nitride.

### SUMMARY OF THE INVENTION

The present invention is directed to a chemical mechanical polishing composition, comprising, as initial components:

water;

a colloidal silica abrasive;

one or more acidic heterocyclic nitrogen compounds having a pK of less than or equal to 5 and chosen from triazoles and tetrazoles;

optionally, a biocide;
optionally, a buffer; and, wherein a pH of the chemical mechanical polishing composition is 5 or less.

The present invention is further directed to a method for chemical mechanical polishing of a substrate, comprising,

providing a substrate, wherein the substrate comprises silicon dioxide and silicon nitride;

providing a chemical mechanical polishing composition comprising, as initial components:

water;

a colloidal silica abrasive;

one or more acidic heterocyclic nitrogen compounds having a pK of less than or equal to 5 and chosen from triazoles and tetrazoles;

optionally, a biocide;
optionally, a buffer; and, wherein a pH of the chemical mechanical polishing composition is 5 or less; and,

providing a chemical mechanical polishing pad with a polishing surface;

creating dynamic contact at an interface between the polishing surface of the chemical mechanical polishing pad and the substrate with a down force of 20.7 kPa; and

dispensing the chemical mechanical polishing composition onto the chemical mechanical polishing pad at or near the interface between the chemical mechanical polishing pad and the substrate;

wherein the substrate is polished; and, wherein at least some of the silicon dioxide and silicon nitride is removed from the substrate.

The chemical mechanical polishing composition and method of the present invention enable selective removal of silicon dioxide over silicon nitride in advanced design devices, such as in FEOL semiconductor processing.

### DETAILED DESCRIPTION OF THE INVENTION

As used throughout this specification the following abbreviations have the following meanings, unless the context indicates otherwise: ° C.=degrees Centigrade; g=grams; L=liters; mL=milliliters; μ=μm=microns; kPa=kilopascal; Å=angstroms; mm=millimeters; cm=centimeter; nm=nanometers; min=minute; rpm=revolutions per minute; mM=millimoles; mV=millivolts; lbs=pounds; kg=kilograms; Kₑ=equilibrium constant; wt %=percent by weight; RR=removal rate; PS=Polishing Slurry of the Invention; PSC=Comparative Polishing Slurry.

The term “chemical mechanical polishing” or “CMP” refers to a process where a substrate is polished by means of chemical and mechanical forces alone and is distinguished from electrochemical-mechanical polishing (ECMP) where an electric bias is applied to the substrate. The term “pK” means the (−) negative log of an acidic heterocyclic nitrogen compound's equilibrium constant in an aqueous solution at room temperature. The term “TEOS” means the silicon oxide formed from the decomposition of tetraethyl orthosilicate (Si(OC₂H₅)₄). The term “composition” and “slurry” are used interchangeably through-out the specification. The “----” dashed line in chemical structures means an optional bond. The term “alkylene (alkanediyl)” is a bivalent saturated carbon radical. The terms “a” and “an” refer to both the singular and the plural. All percentages are by weight, unless otherwise noted. All numerical ranges are inclusive and combinable in any order, except where it is logical that such numerical ranges are constrained to add up to 100%.

The chemical mechanical polishing composition and method of the present invention is useful for polishing a substrate comprising silicon dioxide (TEOS) and silicon nitride (Si₃N₄), wherein silicon dioxide removal rate is selective over silicon nitride removal rate. The chemical mechanical polishing composition used in the method of the present invention contains (preferably consists of) water; a colloidal silica abrasive; one or more acidic heterocyclic nitrogen compounds having a pK (−log of the equilibrium constant) of 5 or less, and the one or more acidic heterocyclic nitrogen compounds are chosen from triazole compounds and tetrazole compounds; optionally a biocide; and, optionally, a buffer; and the chemical mechanical polishing composition has a pH of 5 or less.

The equilibrium constant (Kₑ) can be represented by the following general formula:

Kₑ=[A]^{p}[B]^{q}/[AₚB_{q}],

wherein [A], [B] and [AB] are concentrations of each component and p and q refer to moles. A general equilibrium reaction for the foregoing equation can be represented by the following:

pA+qB⇄AₚB_{q}

The pK of the equilibrium constants of the acidic heterocyclic nitrogen compounds of the present invention ranges from 2 to 5, preferably, from 2 to less than 5, more preferably, from 3 to less than 5, most preferably, from 4 to less than 5. The Kₑ of the acidic heterocyclic nitrogen compounds of the present invention are determined at room temperature, preferably, at 25° C.

The acidic heterocyclic nitrogen compounds chosen from triazoles and tetrazoles of the present invention, preferably, have a general formula (I):

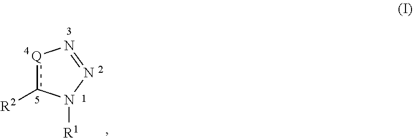

wherein R¹ is selected from the group consisting of —H (hydrogen) and —OH (hydroxyl); Q is selected from the group consisting of C (carbon atom) and N (nitrogen atom); and R² is a substituted or unsubstituted phenyl group, —OH, linear or branched (C₁-C₄)alkyl group when Q is C or N, and R² can be an alkylene group of four carbon atoms when Q is C to form a fused six-membered carbon ring, saturated or unsaturated, substituted or unsubstituted, with the five-membered ring of formula (I) above, and R² can be —H when Q is N. While not being bound by theory, the acidic character of the heterocyclic nitrogen compounds of formula (I) is due to at least the —H or —OH group on the N at position 1. The acidic character of the heterocyclic nitrogen compounds of the present invention enables an acidic aqueous chemical mechanical polishing composition without the addition of other acids or acidic compounds, including buffers, to maintain the desired pH range of less than or equal to 5, preferably, from 2 to 5, more preferably, from 2 to less than 5, most preferably, from 3 to 4.

Substituent groups on the phenyl group and on the six membered carbon ring can include, but are not limited to, hydroxyl, linear or branched hydroxy(C₁-C₄)alkyl, linear or branched (C₁-C₄)alkyl, —NH₂, linear or branched amino(C₁-C₄)alkyl, linear or branched alkoxy(C₁-C₄)alkyl, —NO₂, thiol (—SH), linear or branched thiol(C₁-C₄)alkyl, —CN, linear or branched cyano(C₁-C₄)alkyl, sulfonate (—SO₃), and linear or branched (C₁-C₄)alky sulfonate.

Preferably, R² is a substituted or unsubstituted phenyl group, an alkylene group of four carbon atoms when Q is C to form an unsaturated, substituted or unsubstituted six-membered carbon ring fused with the five-membered ring of formula (I), and, preferably, R² is —H when Q is N, and, preferably R¹ is —H when Q is N. More preferably, R² is unsubstituted phenyl or —H when Q is N and R¹ is —H, and when Q is C, it is, more preferred, that R² is an unsaturated four carbon alkylene group fused with the five-membered ring, wherein the acidic heterocyclic nitrogen compound of the present invention has a benzotriazole formula (II):

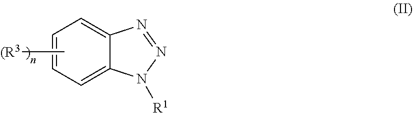

wherein R¹ is —H or —OH, and R³ is a substituent group as described above, more preferably, R³ is a substituent group independently chosen from hydroxyl, —NH₂, —NO₂, thiol (—SH), sulfonate (—SO₃), and n is 0-3, wherein n=0, there are no substituent groups on the ring. Most preferably, n=0 and R¹ is —OH for formula (II).

Exemplary compounds of the present invention wherein Q is N, R¹ is —H and R² is —H or phenyl of formula (I) are tetrazole and 5-phenyl-1H-tetrazole. An exemplary acidic heterocyclic nitrogen compound of formula (II) is 1-hydroxy benzotriazole.

Acidic heterocyclic nitrogen compounds of the present invention are included in the chemical mechanical polishing compositions of the present invention, as an initial component, in amounts of at least 0.1 mM, preferably from 0.1-10 mM, more preferably from 1-5 mN, most preferably from 2-4 mM.

The water contained in the chemical mechanical polishing composition used in the chemical mechanical polishing method of the present invention is, preferably, at least one of deionized and distilled to limit incidental impurities.

In accordance with the chemical mechanical polishing compositions of the present invention, colloidal silica compositions include, but are not limited to, a dispersion of silica made by conventional sol gel polymerization or by the suspension polymerization of water glass to produce a plurality of elongated, bent or nodular silica particles in a distribution or mixture that can include a plurality of spherical silica particles. It is preferred that the abrasive colloidal silica particles of the present invention have a (+) positive zeta potential. It is most preferred that the abrasive colloidal silica particles of the present invention have a permanent (+) positive zeta potential.

Dispersions of elongated, bent or nodular colloidal silica particles can be made from suspension polymerization by hydrolytic condensation of silanols formed in a known manner from precursors like tetraethoxysilane (TEOS) or tetramethoxysilane (TMOS). Processes for making the elongated, bent or nodular silica particles are known and can be found, for example, in U.S. Pat. No. 8,529,787 to Higuchi et al. The hydrolytic condensation includes reacting the precursors in aqueous suspension in the presence of a basic catalyst, such as alkylammonium hydroxides, alkoxyalkyl amines, such as ethoxypropylamine (EOPA), alkylamines or potassium hydroxide, preferably, tetramethylammonium hydroxide. The hydrolytic condensation process can incorporate one or more cationic nitrogen atoms into the elongated, bent or nodular silica particles. Preferably, the elongated, bent or nodular silica particles are cationic at a pH of 4 or below.

Dispersions of bent or nodular colloidal silica particles are available from Fuso Chemical Co., Ltd., Osaka, Japan (Fuso) under the tradenames HL-2, HL-3, HL-4, PL-2, PL3 or BS-2 and BS-3 slurries. Other abrasives include, but are not limited to, HL-1 and BS series abrasives, such as BS-1, BS-2 and BS-3 (Fuso). The HL and BS series particles from Fuso contain one or more nitrogen atoms which impart a cationic charge at pH 4 or below.

Preferably, the colloidal silica has an average particle size of <200 nm, more preferably, 75 to 150 nm, most preferably, 100 to 150 nm; and is included in the chemical mechanical polishing composition of the present invention, as an initial component, in amounts of 0.1 to 40 wt %, preferably, 0.5 to 25 wt %, more preferably, 1 to 12 wt %.

The colloidal silica abrasive particles of the chemical mechanical polishing compositions of the present invention preferably have a (+) positive zeta potential. Preferably, the colloidal silica particles of the chemical mechanical polishing compositions of the present invention have a zeta potential of (+) 5 to (+) 50 mV.

Optionally, the chemical mechanical polishing composition used in the chemical mechanical polishing method of the present invention further contains additional additives chosen from one or more of buffers, pH adjusting agents, anti-foaming agents, surfactants and biocides.

Optional biocides include, but are not limited to, KORDEK™ MLX (9.5-9.9% methyl-4-isothiazolin-3-one, 89.1-89.5% water and ≤1.0% related reaction product) or KATHON™ ICP III containing active ingredients of 2-methyl-4-isothiazolin-3-one and 5-chloro-2-methyl-4-isothiazolin-3-one, each manufactured by The Dow Chemical Company, (KATHON and KORDEK are trademarks of The Dow Chemical Company). It is preferred that biocides are included in the chemical mechanical polishing composition.

Biocides can be included in the chemical mechanical polishing composition of the present invention, as an initial component, in amounts of 0.001 wt % to 0.1 wt %, preferably, 0.001 wt % to 0.05 wt %, more preferably, 0.01 wt % to 0.05 wt %, still more preferably, 0.01 wt % to 0.025 wt %.

Optionally, the chemical mechanical polishing composition can further include defoaming agents, such as non-ionic surfactants including esters, ethylene oxides, alcohols, ethoxylate, silicon compounds, fluorine compounds, ethers, glycosides and their derivatives. Anionic ether sulfates such as sodium lauryl ether sulfate (SLES) as well as the potassium and ammonium salts. The surfactant can also be an amphoteric surfactant.

Optionally, the chemical mechanical polishing composition of the present invention can contain, as an initial component, 0.001 wt % to 0.1 wt %, preferably, 0.001 wt % to 0.05 wt %, more preferably, 0.01 wt % to 0.05 wt %, still more preferably, 0.01 wt % to 0.025 wt %, of an anti-foam agent or surfactant. It is preferred that anti-foam agents and surfactants are excluded from the chemical mechanical polishing compositions of the present invention.

The chemical mechanical polishing composition of the present invention can optionally include one or more pH adjusting agents to maintain the pH within a preferred range. Preferably, the pH adjusting agent is chosen from one or more of sodium hydroxide, potassium hydroxide, and ammonia. It is preferred that such pH adjusting agents are excluded from the chemical mechanical polishing compositions of the present invention.

The chemical mechanical polishing pad used in the chemical mechanical polishing method of the present invention can be any suitable polishing pad known in the art. The chemical mechanical polishing pad can, optionally, be chosen from woven and non-woven polishing pads. The chemical mechanical polishing pad can be made of any suitable polymer of varying density, hardness, thickness, compressibility and modulus. The chemical mechanical polishing pad can be grooved and perforated as desired.

The chemical mechanical polishing composition used in the chemical mechanical polishing method of the present invention enables operation with a low nominal polishing pad pressure, for example at 3 to 35 kPa. The low nominal polishing pad pressure improves polishing performance by reducing scratching and other undesired polish defects and minimizes damage to fragile materials.

In the method of polishing a substrate of the present invention, the chemical mechanical polishing composition provided has a silicon dioxide removal rate ≥1000 Å/min; preferably, ≥1800 Å/min; more preferably, ≥1900 Å/min; and a TEOS:Si₃N₄ selectivity of ≥5:1; preferably, a TEOS:Si₃N₄ selectivity of ≥20:1; more preferably, a TEOS:Si₃N₄ selectivity of ≥30:1; still more preferably, a TEOS:Si₃N₄ selectivity of ≥35:1; and, with a platen speed of 93 revolutions per minute, a carrier speed of 87 revolutions per minute, a chemical mechanical polishing composition flow rate of 200 mL/min, a nominal down force of 20.7 kPa on a 200 mm polishing machine; and, wherein the chemical mechanical polishing pad comprises a polyurethane polishing layer containing polymeric hollow core microparticles and a polyurethane impregnated non-woven subpad.

The following examples are intended to illustrate the present invention but are not intended to limits its scope.

### EXAMPLE 1

### Chemical Mechanical Polishing Compositions

The following chemical mechanical polishing compositions are polishing slurries and were prepared to include the components and amounts disclosed in Table 1 below. The components were combined with the balance being deionized water without further adjustment of the pH or addition of buffers.

TABLE 1

| | | | | Additive | | |
|---|---|---|---|---|---|---|
| | | Abrasive | | Amount | | |
| Slurry # | Abrasive | (wt %) | Additive | (mM) | pH | pK |
| PS-1 | HL-3 | 1 | 1-Hydroxy | 2 | 3.7 | 4.3 |
| | | | benzotriazole | | | |
| PS-2 | HL-3 | 1 | 1-Hydroxy | 1 | 3.9 | 4.3 |
| | | | benzotriazole | | | |
| PS-3 | HL-3 | 1 | 5-phenyl- | 2 | 3.6 | 4.5 |
| | | | 1H-tetrazole | | | |
| PS-4 | HL-3 | 1 | 5-phenyl- | 1 | 3.8 | 4.5 |
| | | | 1H-tetrazole | | | |
| PS-5 | BS-3 | 1 | 5-phenyl- | 4 | 3.7 | 4.5 |
| | | | 1H-tetrazole | | | |
| PSC-1 | HL-3 | 1 | 1,2,4-triazole | 4 | 8.1 | 10.3 |
| PSC-2 | HL-3 | 1 | Imidazole | 4 | 8.1 | 14.4 |
| PSC-3 | HL-3 | 1 | 3-hydroxy | 4 | 8.1 | 8.8 |
| | | | pyridine | | | |

HL-3 and BS-3 colloidal silica particles are available from Fuso Chemical Co., Ltd, Japan.

### EXAMPLE 2

### TEOS vs. Si₃N₄ Polishing and Removal Rate

Blanket wafer removal rate testing from polishing on each of tetraethoxy silane (TEOS) and silicon nitride substrates was performed using a Strasburgh 6EC 200 mm wafer polisher or “6EC RR” (Axus Technology Company, Chandler, Ariz.) at a downforce of 20.7 kPa (3 psi) and table and carrier revolution rates (rpm), respectively, of 93 and 87, and with an IC1000™ CMP polishing pad having a 1010 groove pattern (Dow, Midland, Mich.) and the indicated abrasive slurry, as shown in Table 2, below, at a given abrasive slurry flow rate 200 mL/min. A SEASOL™ AK45 AM02BSL8031C1 diamond pad conditioner disk (Kinik Company, Taiwan) was used to condition the polishing pad. The polishing pad was conditioned in situ during polishing using a down force of 3.18 kg (7.0 lbf) at 10 sweeps/min from 4.32 cm to 23.37 cm from the center of the polishing pad. The removal rates were determined by measuring the film thickness before and after polishing using a KLA-TENCOR™ FX200 metrology tool (KLA TENCOR, Milpitas, Calif.) using a 49 point spiral scan with a 3 mm edge exclusion. Removal Rate results and their ratios (selectivity) are shown in Table 2, below.

TABLE 2

| | Zeta potential | TEOS RR | Si₃N₄ RR | TEOS: Si₃N₄ |
|---|---|---|---|---|
| Slurry # | (mV) | (Å/min) | (Å/min) | Selectivity |
| PS-1 | 23 | 1937 | 90 | 22 |
| PS-2 | 19 | 1830 | 403 | 5 |
| PS-3 | 24 | 1978 | 59 | 33 |
| PS-4 | 22 | 1947 | 336 | 6 |
| PS-5 | 13 | 1398 | 38 | 37 |
| PSC-1 | −41 | 8 | 7 | 1 |
| PSC-2 | −49 | 11 | 17 | 1 |
| PSC-3 | −45 | 10 | 13 | 1 |

1-4. (canceled)

5. A method for chemical mechanical polishing of a substrate, comprising:
providing a substrate, wherein the substrate comprises silicon dioxide and silicon nitride;
providing a chemical mechanical polishing composition comprising, as initial components:
water;
a colloidal silica abrasive;
one or more acidic heterocyclic nitrogen compounds having a pK of less than or equal to 5 and chosen from triazoles and tetrazoles;
optionally, a biocide;
optionally, a buffer; and wherein a pH of the chemical mechanical polishing composition is 5 or less; and
providing a chemical mechanical polishing pad with a polishing surface;
creating dynamic contact at an interface between the polishing surface of the chemical mechanical polishing pad and the substrate with a down force of 20.7 kPa; and
dispensing the chemical mechanical polishing composition onto the chemical mechanical polishing pad at or near the interface between the chemical mechanical polishing pad and the substrate;
wherein the substrate is polished; and, wherein at least some of the silicon dioxide and silicon nitride is removed from the substrate.

6. The method of claim 5, wherein the chemical mechanical polishing composition provided comprises, as initial components:
water;
0.1 to 40 wt % of the colloidal silica abrasive, wherein the colloidal silica abrasive is a colloidal silica abrasive having a positive zeta potential;
at least 0.1 mM of the one or more of the acidic heterocyclic nitrogen compounds having a pK from 2 to 5 and chosen from triazoles and tetrazole;
optionally, a biocide;
optionally, a buffer, and, wherein a pH of the chemical mechanical polishing composition is 5 or less.

7. The method of claim 6, wherein the chemical mechanical polishing composition comprises, as initial components:
water;
0.5 to 25 wt % of the colloidal silica abrasive, wherein the colloidal silica abrasive has a positive zeta potential;
0.1 to 10 mM of the one or more of the acidic heterocyclic nitrogen compounds having a pK from 3 to less than 5 and chosen from triazoles and tetrazoles, wherein the triazoles and tetrazoles have a general formula: 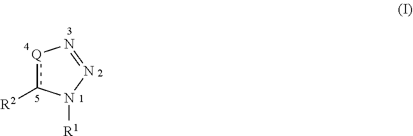
wherein R¹ is selected from the group consisting of —H and —OH; Q is selected from the group consisting of a carbon atom and a nitrogen atom; and R² is a substituted or unsubstituted phenyl group, —OH, linear or branched (C₁-C₄)alkyl group when Q is carbon atom or nitrogen atom, and R² can be an alkylene group of four carbon atoms, when Q is a carbon atom to form a fused six-membered carbon ring, saturated or unsaturated, substituted or unsubstituted, with the five-membered ring of formula (I), and R² can be —H when Q is a nitrogen atom;
the biocide;
optionally, a buffer; and, wherein a pH of the chemical mechanical polishing composition is 2 to 5.

8. The method of claim 7, wherein the triazole is a benzotriazole having a general formula: 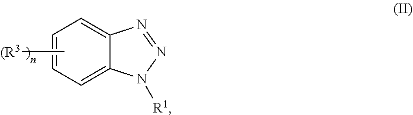
wherein R¹ is selected from the group consisting of —H and —OH, and R³ is a substituent group independently chosen from hydroxyl, linear or branched hydroxy(C₁-C₄)alkyl, linear or branched (C₁-C₄)alkyl, —NH₂, linear or branched amino(C₁-C₄)alkyl, linear or branched alkoxy(C₁-C₄)alkyl, —NO₂, thiol, linear or branched thiol(C₁-C₄)alkyl, —CN, linear or branched cyano(C₁-C₄)alkyl, sulfonate, and linear or branched (C₁-C₄)alky sulfonate; and n is 0-3, wherein n=0, there are no substituent groups on the ring.
